(19) United States
(12) Patent Application Publication
(10) Pub. No.: US 2023/0299129 A1
(43) Pub. Date: Sep. 21, 2023

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kanako KOMATSU, Yokohama Kanagawa (JP); Yoshiaki ISHII, Kawasaki Kanagawa (JP); Daisuke SHINOHARA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/939,998

(22) Filed: Sep. 8, 2022

(30) Foreign Application Priority Data
Mar. 15, 2022 (JP) 2022-040411

(51) Int. Cl. H01L 29/06

(52) U.S. Cl. CPC H01L 29/0623

(57) ABSTRACT

A semiconductor device includes a semiconductor substrate of a first conductivity type; a semiconductor layer located on the semiconductor substrate, the semiconductor layer being of the first conductivity type and including a first device part; a buried layer located between the semiconductor substrate and the first device part, the buried layer being of a second conductivity type; a guard region located at a first-direction side of the first device part, the guard region being of the second conductivity type, a lower end of the guard region contacting the buried layer, an upper end of the guard region reaching an upper surface of the semiconductor layer, the guard region not being located at a second-direction side of the first device part, the second direction being opposite to the first direction; and a first semiconductor region located inside the first device part and being of the second conductivity type.

### CROSS-REFERENCE TO RELATED APPLICATIONS

This application is based upon and claims the benefit of priority from Japanese Patent Application No. 2022-040411, filed on Mar. 15, 2022; the entire contents of which are incorporated herein by reference.

### FIELD

Embodiments relate to a semiconductor device.

### BACKGROUND

There are cases where a circuit such as a power control circuit or the like handling a large current and a circuit such as a signal processing circuit or the like handling a small current are provided together in a semiconductor device. In such a semiconductor device, there are cases where noise generated in the large current circuit affects the operation of the small current circuit. Therefore, technology has been proposed in which a guard ring region is provided at the periphery of the large current circuit, and the large current circuit is electrically isolated from the periphery by insulating film separation and/or p-n separation. However, downsizing of the semiconductor device is obstructed when the guard ring region is provided.

### BRIEF DESCRIPTION OF THE DRAWINGS

FIG. 1 is a plan view showing a semiconductor device according to a first embodiment;

FIG. 2 is a cross-sectional view along line A-A′ shown in FIG. 1;

FIG. 3 is a cross-sectional view showing a first device part and a guard region according to the first embodiment;

FIG. 4 is a cross-sectional view showing a second device part according to the first embodiment;

FIG. 5 is a plan view showing a semiconductor device according to a first modification of the first embodiment;

FIG. 6 is a plan view showing a semiconductor device according to a second modification of the first embodiment;

FIG. 7 is a plan view showing a semiconductor device according to a third modification of the first embodiment;

FIG. 8A is a plan view showing a semiconductor device according to a second embodiment; and FIG. 8B shows region B of FIG. 8A;

FIG. 9 is a plan view showing a semiconductor device according to a first modification of the second embodiment;

FIG. 10 is a plan view showing a semiconductor device according to a second modification of the second embodiment; and

FIG. 11 is a plan view showing a semiconductor device according to a third embodiment.

### DETAILED DESCRIPTION

In general, according to one embodiment, a semiconductor device includes a semiconductor substrate of a first conductivity type, a semiconductor layer being of the first conductivity type, a buried layer being of a second conductivity type, a guard region being of the second conductivity type, and a first semiconductor region being of the second conductivity type. The semiconductor layer is located on the semiconductor substrate. The semiconductor layer includes a first device part. The buried layer is located between the semiconductor substrate and the first device part. The guard region is located at a first-direction side of the first device part. A lower end of the guard region contacts the buried layer. An upper end of the guard region reaches an upper surface of the semiconductor layer. The guard region is not located at a second-direction side of the first device part. The second direction is opposite to the first direction. The first semiconductor region is located inside the first device part.

According to one embodiment, a semiconductor device includes a semiconductor substrate of a first conductivity type, a semiconductor layer being of a first conductivity type, a buried layer being of a second conductivity type, a guard region being of the second conductivity type, a first semiconductor region being of the second conductivity type, and a second semiconductor region being of the second conductivity type. The semiconductor layer is located on the semiconductor substrate. The semiconductor layer includes a first device part and a second device part. The first device part and the second device part are separated from each other. The buried layer is located between the semiconductor substrate and the first device part. The guard region is located at a first-direction side but not at a second-direction side when viewed from the first device part. The first direction is from the first device part toward the second device part. The second direction is opposite to the first direction. A lower end of the guard region contacts the buried layer. An upper end of the guard region reaches an upper surface of the semiconductor layer. The first semiconductor region is located inside the first device part. The second semiconductor region is located inside the second device part.

According to one embodiment, a semiconductor device includes a semiconductor substrate of a first conductivity type, a semiconductor layer being of the first conductivity type, a buried layer being of a second conductivity type, a guard region being of the second conductivity type, a first semiconductor region being of the second conductivity type, and a second semiconductor region being of the second conductivity type. The semiconductor substrate includes a first end surface parallel to a first direction, and a second end surface parallel to a second direction orthogonal to the first direction. The semiconductor layer is located on the semiconductor substrate. The semiconductor layer includes a first device part, and a second device part separated from the first device part in the first and second directions. The buried layer is located between the semiconductor substrate and the first device part. The guard region is located at the first-direction side and the second-direction side when viewed from the first device part. The guard region is not located at a third-direction side or at a fourth-direction side when viewed from the first device part. The third direction is opposite to the first direction. The fourth direction is opposite to the second direction. A lower end of the guard region contacts the buried layer. An upper end of the guard region reaches an upper surface of the semiconductor layer. The first semiconductor region is located inside the first device part. The second semiconductor region is located inside the second device part.

### First Embodiment

A first embodiment will now be described.

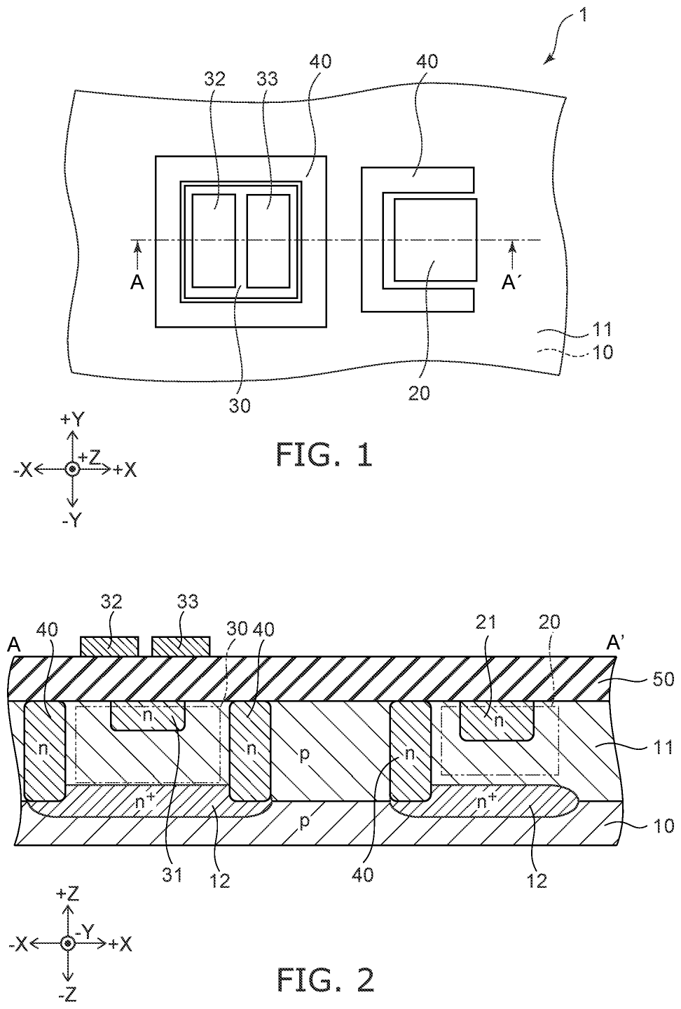

FIG. 1 is a plan view showing a semiconductor device according to the embodiment.

FIG. 2 is a cross-sectional view along line A-A′ shown in FIG. 1.

The drawings are schematic; and the components are simplified, not illustrated, or emphasized as appropriate. The numbers and dimensional ratios of the components do not always match between the drawings. This is similar for the other drawings described below as well.

First, the configuration of the semiconductor device according to the embodiment will be summarily described.

As shown in FIGS. 1 and 2, the semiconductor device 1 according to the embodiment is a device in which two types of circuits are provided together in one chip. Hereinbelow, the two types of circuits are called a “small current circuit” and a “large current circuit” for convenience. At least a portion of the small current circuit is formed in a first device part 20 described below; and at least a portion of the large current circuit is formed in a second device part 30 described below.

The semiconductor device 1 includes a semiconductor substrate 10. For example, the semiconductor substrate 10 is made of single-crystal silicon; and the conductivity type of the semiconductor substrate 10 is, for example, a p-type. A semiconductor layer 11 is located on the semiconductor substrate 10. For example, the semiconductor layer 11 is made of single-crystal silicon epitaxially grown using the upper surface of the semiconductor substrate 10 as a starting point; and the conductivity type of the semiconductor layer 11 is the p-type.

The first device part 20 and the second device part 30 are set in the semiconductor layer 11. The first device part 20 and the second device part 30 are separated from each other. A buried layer 12 of the n⁺-type is located between the semiconductor substrate 10 and the first device part 20 of the semiconductor layer 11 and between the second device part 30 and the semiconductor substrate 10. An inter-layer insulating film 50 is located on the semiconductor layer 11. The inter-layer insulating film 50 is not illustrated in FIG. 1.

An XYZ orthogonal coordinate system is employed for convenience of description in the specification hereinbelow. Among directions parallel to the interface between the semiconductor substrate 10 and the semiconductor layer 11, the direction from the first device part 20 toward the second device part 30 is taken as a “−X direction”; and the opposite direction is taken as a “+X direction”. Also, among directions parallel to the interface between the semiconductor substrate 10 and the semiconductor layer 11, one direction orthogonal to the +X direction is taken as a “+Y direction”; and the opposite direction is taken as a “−Y direction”. The direction from the semiconductor substrate 10 toward the semiconductor layer 11 is taken as a “+Z direction”; and the opposite direction is taken as a “−Z direction”. The +Z direction also is called “up”, and the −Z direction also is called “down”; however, these expressions are for convenience and are independent of the direction of gravity. The +X direction and the −X direction also are generally referred to as simply the “X-direction”. This is similar for the Y-direction and the Z-direction as well.

For example, the shapes of the first and second device parts 20 and 30 when viewed from above (the +Z direction) are rectangular. A pair of end surfaces of the first device part 20 is parallel to the X-direction; and the other pair of end surfaces is parallel to the Y-direction. Similarly, a pair of end surfaces of the second device part 30 is parallel to the X-direction; and the other pair of end surfaces is parallel to the Y-direction.

A portion of the small current circuit handling the small current is formed in the first device part 20. The small current circuit is, for example, a signal processing circuit, e.g., a digital circuit. A deep n-well 21 (a first semiconductor region) of the n-type is located in the first device part 20.

On the other hand, a portion of the large current circuit handling the large current is formed in the second device part 30. The large current circuit is, for example, a current control circuit, e.g., an analog circuit. An n-well 31 (a second semiconductor region) of the n-type is located in the second device part 30. A source pad 32 and a drain pad 33 are separated from each other on the inter-layer insulating film 50. For example, the source pad 32 and the drain pad 33 are connected to a power supply line or a load of a motor, etc.

As described below, the source pad 32 and the drain pad 33 are connected to one part of the large current circuit formed in the second device part 30. Although the source pad 32 and the drain pad 33 are located in a region directly above the second device part 30 in the example shown in FIGS. 1 and 2, the arrangement is not limited thereto; for example, the source pad 32 and the drain pad 33 may be located over substantially the entire upper surface of the semiconductor device 1.

A guard region 40 of the n-type is located at the −X direction side, the +Y direction side, and the −Y direction side when viewed from the first device part 20. In other words, when viewed from above, the guard region 40 has a C-shaped configuration surrounding three sides of the first device part 20. The lower end of the guard region 40 contacts the buried layer 12. The upper end of the guard region 40 reaches the upper surface of the semiconductor layer 11.

In the five directions other than the +X direction, the first device part 20 is electrically isolated from the periphery by the buried layer 12, the guard region 40, and the inter-layer insulating film 50. On the other hand, the guard region 40 is not located in the +X direction of the first device part 20. Therefore, the first device part 20 is electrically continuous with the part of the semiconductor layer 11 other than the first device part 20 in the +X direction.

When viewed from the second device part 30, the n-type guard region 40 is located at the +X direction side, the −X direction side, the +Y direction side, and the −Y direction side. In other words, when viewed from above, the guard region 40 has a frame shape surrounding the second device part 30. The lower end of the guard region 40 contacts the buried layer 12. The upper end of the guard region 40 reaches the upper surface of the semiconductor layer 11. The second device part 30 is electrically isolated from the periphery in all directions by the buried layer 12, the guard region 40, and the inter-layer insulating film 50.

A detailed configuration example of the first device part 20 and the guard region 40 will now be described.

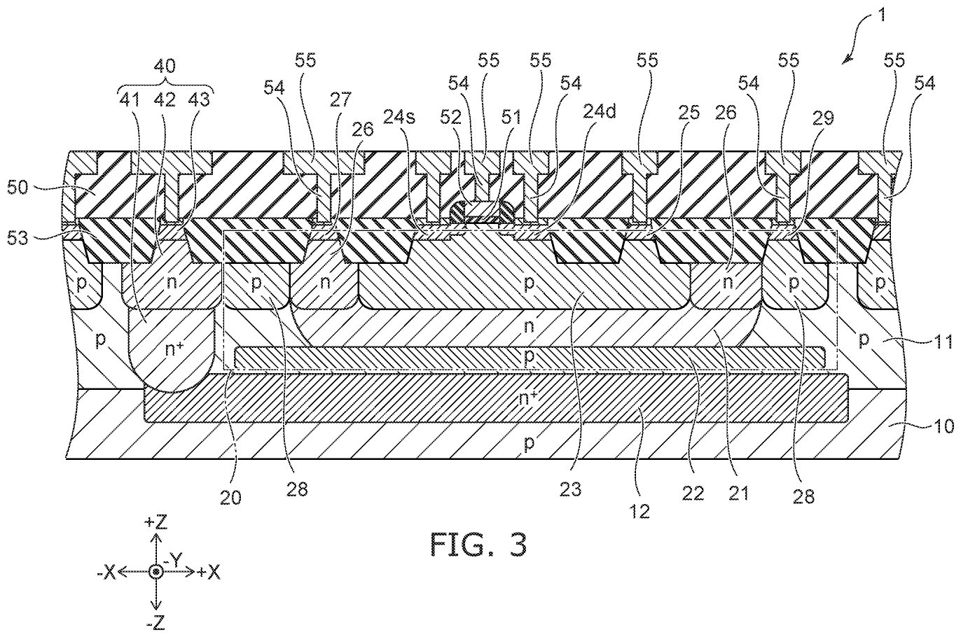

FIG. 3 is a cross-sectional view showing the first device part and the guard region according to the embodiment.

The configuration of the first device part 20 and the guard region 40 described below is an example and is not limited to the example. This is similar for the configuration of the second device part 30 described below as well.

As shown in FIG. 3, a deep p-well 22 of the p-type is located in the first device part 20 of the semiconductor layer 11. The impurity concentration of the deep p-well 22 is greater than the impurity concentration of the semiconductor layer 11. In the specification, “impurity concentration” refers to the impurity concentration affecting the conduction characteristics of the semiconductor and refers to the effective concentration excluding the cancelled portion when one region includes both an impurity that forms acceptors and an impurity that forms donors.

The deep n-well 21 is located on the deep p-well 22. A p-well 23 of the p-type is located in the central part of the upper part of the deep n-well 21. The impurity concentration of the p-well 23 is greater than the impurity concentration of the semiconductor layer 11 and less than the impurity concentration of the deep p-well 22. A source region 24s and a drain region 24d of the n⁺-type are separated from each other in a portion of the upper layer part of the p-well 23. The impurity concentrations of the source region 24s and the drain region 24d are greater than the impurity concentration of the deep n-well 21. A contact region 25 of the p⁺-type is located in another portion of the upper layer part of the p-well 23. The impurity concentration of the contact region 25 is greater than the impurity concentration of the p-well 23.

An n-well 26 of the n-type is located at the periphery of the p-well 23 in the upper part of the deep n-well 21. The impurity concentration of the n-well 26 is greater than the impurity concentration of the deep n-well 21. A contact region 27 of the n⁺-type is located in a portion of the upper layer part of the n-well 26. The impurity concentration of the contact region 27 is greater than the impurity concentration of the n-well 26.

A p-well 28 of the p-type is located at the periphery of the deep n-well 21 in the upper part of the semiconductor layer 11. The impurity concentration of the p-well 28 is greater than the impurity concentration of the semiconductor layer 11 and less than the impurity concentration of the deep p-well 22. A contact region 29 of the p⁺-type is located in a portion of the upper layer part of the p-well 28. The impurity concentration of the contact region 29 is greater than the impurity concentration of the p-well 28.

A gate insulating film 51 is located on the p-well 23 in a region directly above a channel region between the source region 24s and the drain region 24d. For example, the gate insulating film 51 is formed of silicon oxide. A gate electrode 52 is located on the gate insulating film 51. The gate insulating film 51 and the gate electrode 52 are located inside the inter-layer insulating film 50.

In the first device part 20, a MOSFET (Metal-Oxide-Semiconductor Field-Effect Transistor) is formed of the source region 24s, the drain region 24d, the p-well 23, the gate insulating film 51, and the gate electrode 52. Although only one MOSFET is shown in FIG. 3 to simplify the drawing, many such MOSFETs may be located in the first device part 20.

In the guard region 40, a guard ring layer 41 of the n⁺-type, an n-well 42 of the n-type, and a contact region 43 of the n⁺-type are located in this order upward from below. The lower end of the guard ring layer 41 contacts the end part of the buried layer 12 at the −X direction side, the end part of the buried layer 12 at the +Y direction side, and the end part of the buried layer 12 at the −Y direction side. The lower end of the n-well 42 contacts the upper end of the guard ring layer 41. The contact region 43 contacts the upper end of the n-well 42. Thereby, the n-type guard region 40 that is made of the guard ring layer 41, the n-well 42, and the contact region 43 extends through the p-type semiconductor layer 11 in the Z-direction. In other words, the lower end of the guard region 40 contacts the buried layer 12; and the upper end of the guard region 40 reaches the upper surface of the semiconductor layer 11.

The STI (Shallow Trench Isolation (element-separation insulating film)) 53 is located in the region of the upper part of the semiconductor layer 11 other than the source region 24s, the drain region 24d, the channel region between the source region 24s and the drain region 24d, the contact region 25, the contact region 27, the contact region 29, and the contact region 43. The STI 53 is made of, for example, silicon oxide. The STI 53 is located below the inter-layer insulating film 50.

Multiple contacts 54 and multiple interconnects 55 are located inside the inter-layer insulating film 50. The gate electrode 52, the source region 24s, the drain region 24d, the contact region 25, the contact region 27, the contact region 29, and the contact region 43 are connected respectively to the interconnects 55 via the contacts 54.

A detailed configuration example of the second device part 30 will now be described.

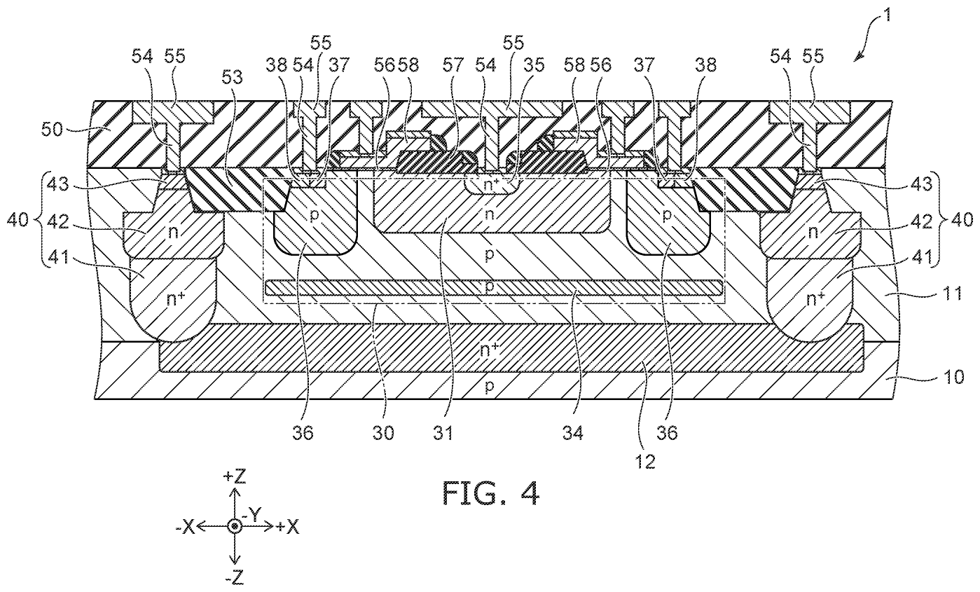

FIG. 4 is a cross-sectional view showing the second device part according to the embodiment.

As shown in FIG. 4, a deep p-well 34 of the p-type is located in the second device part 30 of the semiconductor layer 11. The impurity concentration of the deep p-well 34 is greater than the impurity concentration of the semiconductor layer 11. The n-well 31 described above is located on the deep p-well 34. The n-well 31 is separated from the deep p-well 34 by the semiconductor layer 11. A drain region 35 of the n⁺-type is located in the central part of the upper part of the n-well 31. The impurity concentration of the drain region 35 is greater than the impurity concentration of the n-well 31.

A p-well 36 of the p-type is separated from the n-well 31 at the periphery of the n-well 31 in the upper part of the semiconductor layer 11. The impurity concentration of the p-well 36 is greater than the impurity concentration of the semiconductor layer 11. A source region 37 of the n⁺-type and a contact region 38 of the p⁺-type are located in a portion of the upper layer part of the p-well 36. The impurity concentration of the contact region 38 is greater than the impurity concentration of the p-well 36. The drain region 35 is sandwiched between a pair or multiple pairs of the source region 37 and the contact region 38.

A gate insulating film 56 is located on a part of the p-well 36 between the source region 37 and the semiconductor layer 11, on a channel region of the semiconductor layer 11 between the p-well 36 and the n-well 31, and on a part of the n-well 31 at the p-well 36 side. When viewed from above, a step insulating film 57 is located between the gate insulating film 56 and the drain region 35. The step insulating film 57 is located on the n-well 31 and contacts the gate insulating film 56. The step insulating film 57 is thicker than the gate insulating film 56. For example, the gate insulating film 56 and the step insulating film 57 are formed of silicon oxide. A gate electrode 58 is located on the gate insulating film 56, and on the step insulating film 57. The gate insulating film 56, the step insulating film 57, and the gate electrode 58 is located inside the inter-layer insulating film 50.

The gate electrode 58, the source region 37, the contact region 38, and the drain region 35 are connected respectively to the interconnects 55 via the contacts 54. The source region 37 is connected to the source pad 32 via one contact 54 and one interconnect 55 (see FIGS. 1 and 2). The drain region 35 is connected to the drain pad 33 via another contact 54 and another interconnect 55 (see FIGS. 1 and 2).

In the second device part 30, a LDMOS (Laterally Double-Diffused MOSFET) is formed of the source region 37, the p-well 36, the channel region of the semiconductor layer 11 between the p-well 36 and the n-well 31, the n-well 31, the drain region 35, the gate insulating film 56, the step insulating film 57, and the gate electrode 58. Although only one pair of LDMOSs is shown in FIG. 4 to simplify the drawing, multiple pairs of LDMOSs may be located in the second device part 30.

The buried layer 12 of the n⁺-type is located also between the semiconductor substrate 10 and the second device part 30. When viewed from above, the guard region 40 surrounds the second device part 30. The cross-sectional structure of the guard region 40 is as described above. The buried layer 12 and the guard region 40 may not be provided at the periphery of the second device part 30.

Operations of the semiconductor device according to the embodiment will now be described.

In the semiconductor device 1, a reference potential is applied to the guard region 40 and the buried layer 12 via the contact region 43. For example, the reference potential is set to the ground potential. The first device part 20 and the second device part 30 are driven in this state.

For example, in the first device part 20 as shown in FIG. 3, a first source potential, e.g., the ground potential is applied to the source region 24s; and a first drain potential that is greater than the first source potential is applied to the drain region 24d. The MOSFET is switched on/off by applying a first gate potential to the gate electrode 52 in this state.

In the second device part 30 as shown in FIG. 4, a second source potential, e.g., the ground potential is applied to the source region 37; and a second drain potential that is greater than the second source potential is applied to the drain region 35. For example, the second drain potential is greater than the first drain potential. The LDMOS is switched on/off by applying a second gate potential to the gate electrode 58 in this state.

There are cases where negative carriers are injected into the drain region 35 of the second device part 30. In such a case, for example, the negative carriers are injected into the drain region 35 in the shoot-through prevention period of the H-bridge output or the step-down circuit of the power supply output. For example, when the drain pad 33 is connected to a load such as a motor, etc., and when the LDMOS of the second device part 30 is turned off, negative carriers may be injected into the drain region 35 via the drain pad 33, the interconnect 55, and the contact 54.

When the negative carriers are injected into the drain region 35, the potential of the drain region 35 drops below the source potential (e.g., the ground potential). A forward voltage is applied to the parasitic diode made of the p-type semiconductor layer 11 and the n-well 31; and the parasitic diode conducts. Therefore, a current flows in the order of the contact region 38, the p-well 36, the semiconductor layer 11, the n-well 31, and the drain region 35. The potential of the semiconductor layer 11 is caused to drop thereby, and an electron current flows in the semiconductor substrate 10. The operation of the first device part 20 is affected when the electron current reaches the first device part 20 as noise.

As described above, the current that flows through the second device part 30 is greater than the current flowing through the first device part 20. Therefore, the noise that is emitted due to the driving is greater in the second device part 30 than in the first device part 20. On the other hand, the effects of noise introduced from the outside are greater in the first device part 20 than in the second device part 30. Therefore, when the first device part 20 and the second device part 30 are driven simultaneously, the second device part 30 easily becomes an aggressor circuit (Aggressor); and the first device part 20 easily becomes a victim circuit (Victim).

According to the embodiment, the lower surface of the first device part 20 is covered with the n⁺-type buried layer 12, and when viewed from the first device part 20, the end surface at the −X direction side at which the second device part 30 is positioned and the end surfaces at the +Y direction side and the −Y direction side orthogonal to the −X direction are covered with the guard region 40; therefore, the electron current that propagates from the second device part 30 can be pulled to the outside by the guard region 40, and the noise can be reduced.

According to the embodiment, the guard region 40 is not located at the +X direction side, i.e., the side opposite to the second device part 30 when viewed from the first device part 20. Thereby, compared to the case where the guard region 40 is located at the +X direction side of the first device part 20, the semiconductor device 1 can be downsized by the amount of the thickness of the guard region 40.

By not providing the guard region 40 at the +X direction side of the first device part 20, there is a possibility that the noise radiated from the second device part 30 may flow into the first device part 20 from the +X direction side. However, because this noise flows around the buried layer 12 or the guard region 40, the path length from the second device part 30 is long, and attenuation is sufficient. Therefore, the effects on the operation of the first device part 20 are small.

Effects of the embodiment will now be described.

According to the embodiment, the lower surface of the first device part 20 is covered with the buried layer 12; and the end surfaces at three sides are covered with the guard region 40; therefore, the effects on the operation of the first device part 20 of the noise generated in the second device part 30 can be suppressed. As a result, the distance between the first device part 20 and the second device part 30 can be reduced, and the semiconductor device 1 can be downsized. Also, by not providing the guard region 40 at the +X direction side of the first device part 20, the semiconductor device 1 can be downsized while suppressing the effects of the noise.

### First Modification of First Embodiment

A first modification of the first embodiment will now be described.

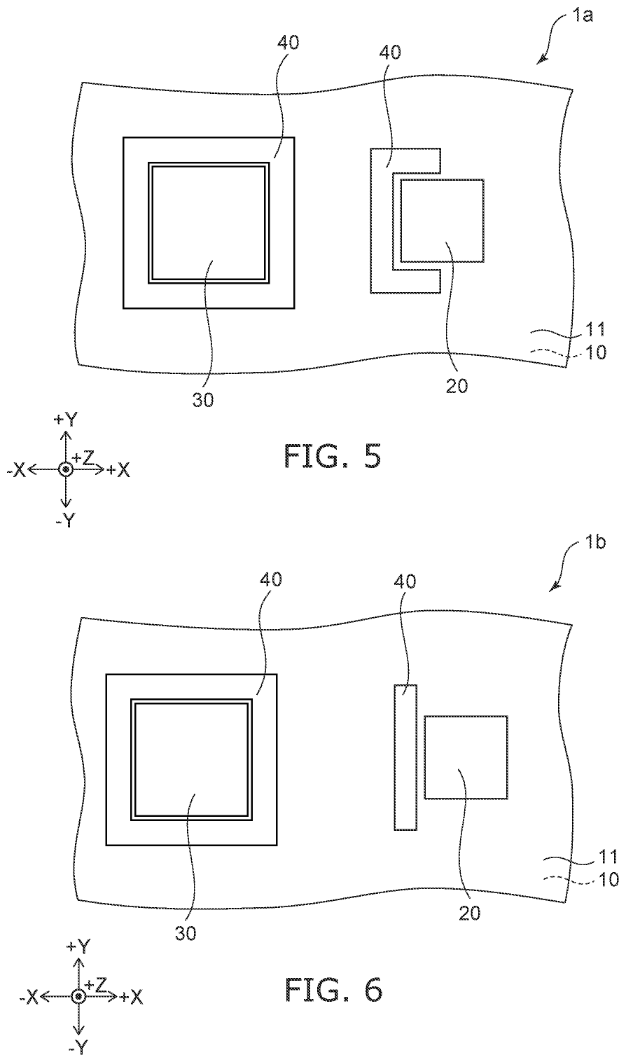

FIG. 5 is a plan view showing a semiconductor device according to the modification.

The inter-layer insulating film 50, the source pad 32, and the drain pad 33 are not illustrated in FIG. 5. This is similar for FIGS. 6 to 10 below as well.

In the semiconductor device 1a according to the modification as shown in FIG. 5, similarly to the first embodiment, the second device part 30 is positioned in the −X direction when viewed from the first device part 20. When viewed from the first device part 20, the guard region 40 is located at the entire −X direction side, at a portion at the −X direction side of a region positioned at the +Y direction side, and at a portion at the −X direction side of a region positioned at the −Y direction side. On the other hand, when viewed from the first device part 20, the guard region 40 is not located at the entire +X direction side, at a portion at the +X direction side of the region positioned at the +Y direction side, or at a portion at the +X direction side of the region positioned at the −Y direction side. The configuration of the first and second device parts 20 and 30 is similar to that of the first embodiment.

Compared to the first embodiment, the semiconductor device according to the modification can be downsized even further by reducing the X-direction length of the guard region 40. The effects of noise can be sufficiently suppressed by the modification when the effects of noise on the first device part 20 according to the modification are less than those of the first embodiment. Otherwise, the configuration, operations, and effects of the modification are similar to those of the first embodiment.

### Second Modification of First Embodiment

A second modification of the first embodiment will now be described.

FIG. 6 is a plan view showing a semiconductor device according to the modification.

In the semiconductor device 1b according to the modification as shown in FIG. 6, similarly to the first embodiment, the second device part 30 is positioned in the −X direction when viewed from the first device part 20. The guard region 40 is located at the entire −X direction side when viewed from the first device part 20. On the other hand, when viewed from the first device part 20, the guard region 40 is not located at the entire +X direction side, the entire +Y direction side, or the entire −Y direction side. In other words, when viewed from above, the guard region 40 has a band shape extending in the Y-direction.

Compared to the first embodiment, the semiconductor device 1b according to the modification can be downsized in the Y-direction because the guard region 40 is not located at the +Y direction side or the −Y direction side of the first device part 20. The semiconductor device can be downsized even further thereby. The effects of noise can be sufficiently reduced by the modification when the first device part 20 of the modification is not easily affected by the noise radiated from the second device part 30 compared to the first modification. Otherwise, the configuration, operations, and effects of the modification are similar to those of the first embodiment.

### Third Modification of First Embodiment

A third modification of the first embodiment will now be described.

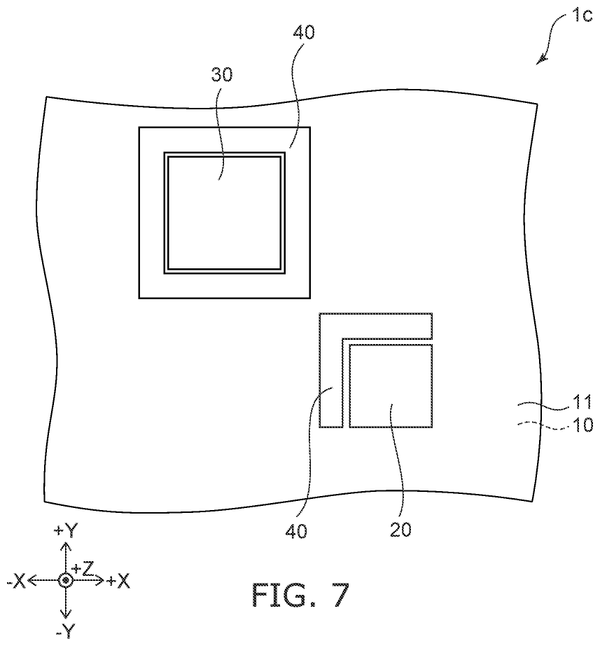

FIG. 7 is a plan view showing a semiconductor device according to the modification.

As shown in FIG. 7, the semiconductor device 1c according to the modification differs from the first embodiment in that the second device part 30 is separated in the −X direction and the +Y direction when viewed from the first device part 20. When viewed from the first device part 20, the guard region 40 is located at the entire −X direction side and at the entire +Y direction side. On the other hand, when viewed from the first device part 20, the guard region 40 is not located at the entire +X direction side or at the entire −Y direction side. In other words, the guard region 40 is L-shaped when viewed from above.

According to the modification, when the second device part 30 is separated in the −X direction and the +Y direction when viewed from the first device part 20, the noise that is radiated from the second device part 30 can be effectively blocked by providing the guard region 40 at the −X direction side and the +Y direction side of the first device part 20. On the other hand, the semiconductor device can be downsized in both the X-direction and the Y-direction by not providing the guard region 40 at +X direction side or the −Y direction side of the first device part 20. Otherwise, the configuration, operations, and effects of the modification are similar to those of the first embodiment.

### Second Embodiment

A second embodiment will now be described.

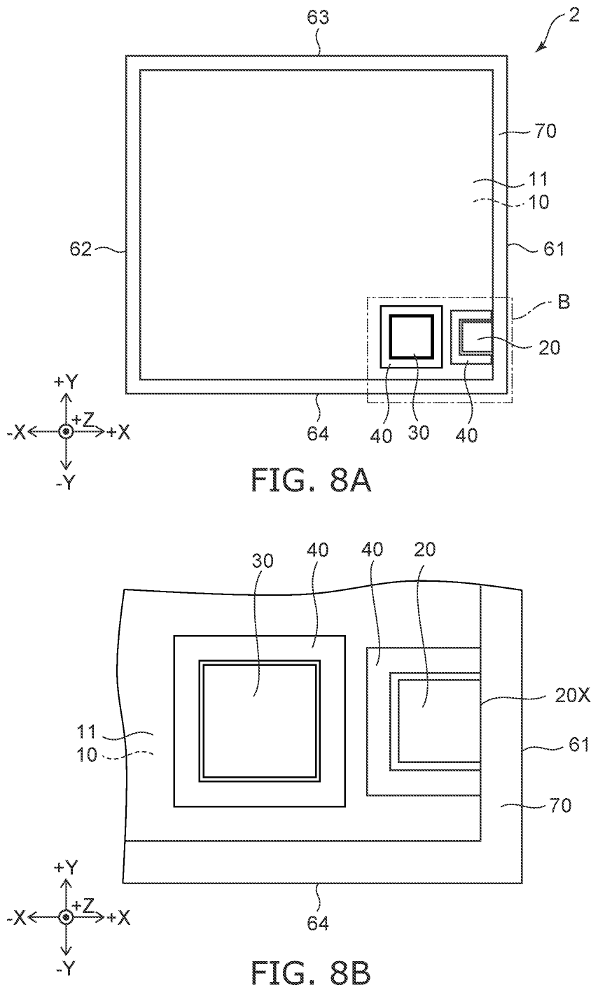

FIG. 8A is a plan view showing a semiconductor device according to the embodiment; and FIG. 8B shows region B of FIG. 8A.

As shown in FIGS. 8A and 8B, the semiconductor device 2 according to the embodiment is chip-shaped and is rectangular when viewed from above. Accordingly, the semiconductor substrate 10 and the semiconductor layer 11 also are rectangular when viewed from above. In addition to the upper surface and the lower surface, the semiconductor device 2 includes four end surfaces 61 to 64. The end surface 61 that faces the +X direction and the end surface 62 that faces the −X direction are parallel to the YZ plane; and the end surface 63 that faces the +Y direction and the end surface 64 that faces the −Y direction are parallel to the XZ plane.

When viewed from above, the peripheral part of the semiconductor device 2 is an end part region 70. The end part region 70 is where the scribe line region was before dicing the wafer; and elements that perform the functions of the semiconductor device 2 are not provided in the end part region 70.

Similarly to the first embodiment, the guard region 40 is located at three sides of the first device part 20, i.e., the −X direction side, the +Y direction side, and the −Y direction side. The guard region 40 is not located at the +X direction side of the first device part 20. The buried layer 12 is located below (at the −Z direction side of) the first device part 20.

On the other hand, the embodiment differs from the first embodiment in that an end surface 20X of the first device part 20 at the +X direction side contacts the end part region 70 and faces the end surface 61 via the end part region 70. In other words, the first device part 20 is located at the end part of the semiconductor device 2 at the +X direction side.

According to the embodiment, the noise propagation path is constrained because the end surface 20X of the first device part 20 at the +X direction side faces the end surface 61 of the semiconductor device 2 via the end part region 70. Thereby, the flow of the noise from the +X direction side toward the first device part 20 can be suppressed. As a result, according to the embodiment, compared to the first embodiment, the flow into the first device part 20 of the noise radiated from the second device part 30 can be more effectively suppressed, and the semiconductor device can be downsized even further. Otherwise, the configuration, operations, and effects according to the embodiment are similar to those of the first embodiment.

### First Modification of Second Embodiment

A first modification of the second embodiment will now be described.

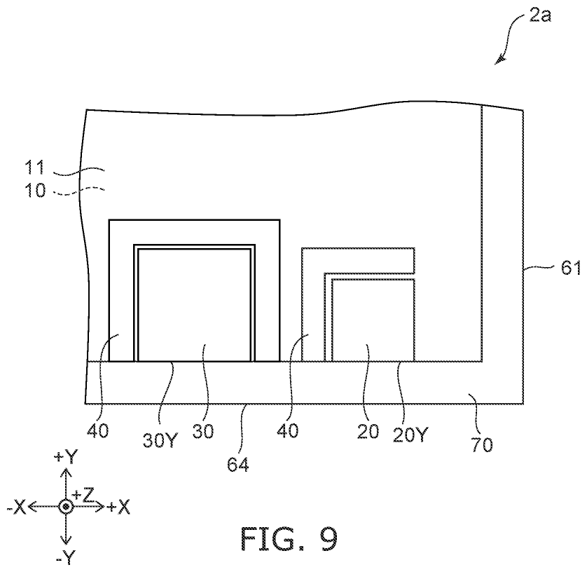

FIG. 9 is a plan view showing a semiconductor device according to the modification.

In the semiconductor device 2a according to the modification as shown in FIG. 9, the guard region 40 is located at the −X direction side and the +Y direction side of the first device part 20, but the guard region 40 is not located at the +X direction side or the −Y direction side of the first device part 20. In other words, the guard region 40 has an L-shape located at the periphery of the first device part 20 when viewed from above.

An end surface 20Y of the first device part 20 at the −Y direction side and an end surface 30Y of the second device part 30 at the −Y direction side contact the end part region 70 and face the end surface 64 of the semiconductor device 2 via the end part region 70. On the other hand, the end surface 20X of the first device part 20 at the +XY-direction side is separated from the end part region 70.

The guard region 40 is located also at the −X direction side, the +X direction side, and the +Y direction side of the second device part 30. The guard region 40 is not located at the −Y direction side of the second device part 30. In other words, the guard region 40 has a C-shaped configuration located at the periphery of the second device part 30.

According to the modification, only the end part region 70 exists at the −Y direction side of the first device part 20 and the −Y direction side of the second device part 30; and the propagation path of the noise is constrained. Therefore, the propagation of noise from the second device part 30 to the first device part 20 can be suppressed even when the guard region 40 is not located at the −Y direction side of the first device part 20. The semiconductor device can be downsized even further by not providing the guard region 40 at the −Y direction side of the first device part 20. Otherwise, the configuration, operations, and effects according to the embodiment are similar to those of the second embodiment.

### Second Modification of Second Embodiment

A second modification of the second embodiment will now be described.

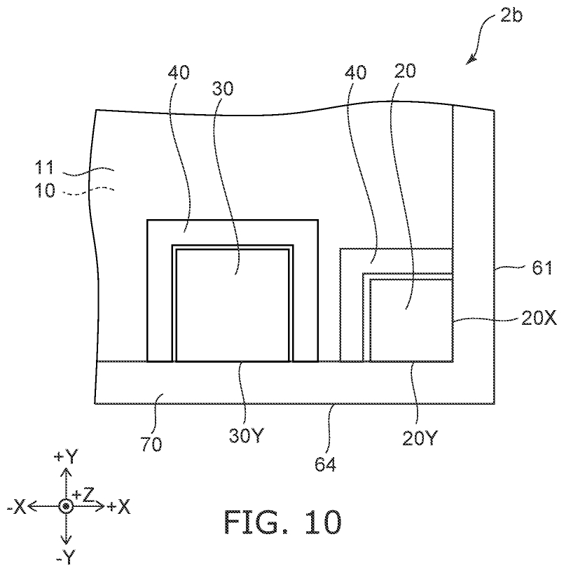

FIG. 10 is a plan view showing a semiconductor device according to the modification.

In the semiconductor device 2b according to the modification as shown in FIG. 10, similarly to the semiconductor device 2a according to the first modification of the second embodiment (see FIG. 9), the guard region 40 is located at the −X direction side and the +Y direction side of the first device part 20; and the guard region 40 is not located at the +X direction side and the −Y direction side of the first device part 20. The shape of the guard region 40 at the periphery of the second device part 30 is similar to that of the first modification of the second embodiment.

The end surface 20Y at the −Y direction side of the first device part 20 and the end surface 30Y at the −Y direction side of the second device part 30 contact the end part region 70 and face the end surface 64 of the semiconductor device 2 via the end part region 70. The end surface 20X at the +X direction side of the first device part 20 also contacts the end part region 70 and faces the end surface 61 of the semiconductor device 2 via the end part region 70. In other words, according to the modification, the first device part 20 faces the end surfaces 64 and 61 of the semiconductor device 2 respectively at the end surface 20Y at the −Y direction side and the end surface 20X at the +X direction side. In other words, the first device part 20 is located at the corners at the +X direction side and the −Y direction side of the semiconductor device 2.

According to the modification, only the end part region 70 exists at the −Y direction side of the first device part 20 and the −Y direction side of the second device part 30; and the propagation path of the noise is constrained. Also, only the end part region 70 exists at the +X direction side of the first device part 20; and the propagation path of the noise is constrained. Therefore, the propagation of the noise from the second device part 30 to the first device part 20 can be suppressed even when the guard region 40 is not located at the −Y direction side and the +X direction side of the first device part 20. As a result, the semiconductor device 2b can be downsized even further. Otherwise, the configuration, operations, and effects according to the embodiment are similar to those of the second embodiment.

### Third Embodiment

A third embodiment will now be described.

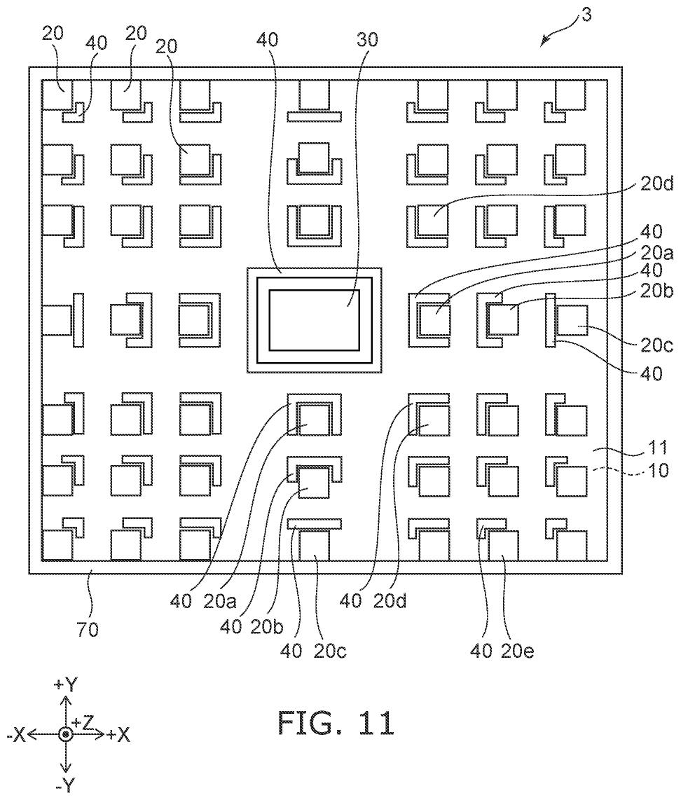

FIG. 11 is a plan view showing a semiconductor device according to the embodiment.

Multiple first device parts 20 and one second device part 30 are included in the semiconductor device 3 according to the embodiment as shown in FIG. 11. The arrangement of the guard region 40 at each first device part 20 is determined according to the positional relationship with the second device part 30.

Specifically, when viewed from above, one second device part 30 is located at the center vicinity of the semiconductor device 3; the multiple first device parts 20 are located around the one second device part 30. For first device parts 20a located at positions proximate to the second device part 30, the guard region 40 is not located at the side opposite to the second device part 30 when viewed from the first device part 20a but is located at the sides of the other three directions as described in the first embodiment (see FIG. 1).

For first device parts 20b located at a medium distance from the second device part 30, the guard region 40 is located at the entire side facing the second device part 30 when viewed from the first device part 20b but only at parts at the second device part 30 side of regions at two sides as described in the first modification of the first embodiment (see FIG. 5).

For first device parts 20c located at positions distant to the second device part 30, the guard region 40 is located only at the side facing the second device part 30 when viewed from the first device part 20c as described in the second modification of the first embodiment (see FIG. 6).

For first device parts 20d located at diagonal positions with respect to the second device part 30, the guard region 40 is located only on two end surfaces facing the second device part 30 when viewed from the first device part 20d as shown in the third modification of the first embodiment (see FIG. 7).

For first device parts 20e contacting the end part region 70 of the chip, the guard region 40 is not located between the first device part 20e and the end surface of the chip as described in the second embodiment (see FIGS. 8A and 8B) and modifications of the second embodiment (see FIGS. 9 and 10).

Thus, by providing the guard region 40 according to the positional relationship between the second device part 30 and each first device part 20, the effective distance of the propagation path of the noise can be not less than a prescribed distance, the effects on the first device part 20 can be suppressed, and the semiconductor device 3 can be downsized. Otherwise, the configuration, operations, and effects according to the embodiment are similar to those of the first embodiment.

Multiple second device parts 30 may be included in the semiconductor device. Also, one guard region 40 may be provided for multiple first device parts 20. In such a case, a common buried layer 12 may be provided for the multiple first device parts 20 corresponding to one guard region 40, or a buried layer 12 may be provided for each first device part 20. By providing the buried layer 12 for each first device part 20, the reference potential can be different for each first device part 20.

According to embodiments described above, a compact semiconductor device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a semiconductor substrate of a first conductivity type;
a semiconductor layer located on the semiconductor substrate, the semiconductor layer being of the first conductivity type and including a first device part;
a buried layer located between the semiconductor substrate and the first device part, the buried layer being of a second conductivity type;
a guard region located at a first-direction side of the first device part, the guard region being of the second conductivity type, a lower end of the guard region contacting the buried layer, an upper end of the guard region reaching an upper surface of the semiconductor layer, the guard region not being located at a second-direction side of the first device part, the second direction being opposite to the first direction; and
a first semiconductor region located inside the first device part, the first semiconductor region being of the second conductivity type.

2. The device according to claim 1, wherein
the guard region is located at a third-direction side and a fourth-direction side of the first device part,
the third direction is orthogonal to the first direction, and
the fourth direction is opposite to the third direction.

3. The device according to claim 1, wherein
the guard region is located at a portion at the first-direction side of a region of the first device part positioned at the third-direction side,
the third direction is orthogonal to the first direction,
the guard region is located at a portion at the first-direction side of a region of the first device part positioned at the fourth-direction side,
the fourth direction is opposite to the third direction,
the guard region is not located at a portion at the second-direction side of the region of the first device part positioned at the third-direction side, and
the guard region is not located at a portion at the second-direction side of the region of the first device part positioned at the fourth-direction side.

4. The device according to claim 1, wherein
the guard region is located at a third-direction side of the first device part,
the third direction is orthogonal to the first direction,
the guard region is not located at a fourth-direction side of the first device part, and
the fourth direction is opposite to the third direction.

5. The device according to claim 1, wherein
the guard region is not located at a third-direction side or at a fourth-direction side of the first device part,
the third direction is orthogonal to the first direction, and
the fourth direction is opposite to the third direction.

6. The device according to claim 1, wherein
the device is rectangular when viewed from above,
the device comprises:
a first end surface parallel to the first direction; and
a second end surface orthogonal to the first end surface, and
an end surface of the first device part at the second-direction side faces the second end surface via an end part region.

7. The device according to claim 4, wherein
the device is rectangular when viewed from above,
the device comprises:
a first end surface parallel to the first direction; and
a second end surface orthogonal to the first end surface,
an end surface of the first device part at the second-direction side faces the second end surface, and
an end surface of the first device part at the fourth-direction side faces the first end surface.

8. The device according to claim 1, further comprising:
a first source region located inside the first device part, the first source region being of the second conductivity type;
a first drain region located inside the first semiconductor region, the first drain region being of the second conductivity type;
a first gate insulating film located on the first device part; and
a first gate electrode located on the first gate insulating film.

9. The device according to claim 1, further comprising:
a second semiconductor region of the second conductivity type,
the semiconductor layer further including a second device part separated in the first direction from the first device part,
the second semiconductor region being located inside the second device part,
at least a portion of the guard region being located between the first device part and the second device part.

10. The device according to claim 9, wherein
a current flowing in the second semiconductor region is greater than a current flowing in the first semiconductor region.

11. A semiconductor device, comprising:
a semiconductor substrate of a first conductivity type;
a semiconductor layer located on the semiconductor substrate, the semiconductor layer being of a first conductivity type and including a first device part and a second device part, the first device part and the second device part being separated from each other;
a buried layer located between the semiconductor substrate and the first device part, the buried layer being of a second conductivity type;
a guard region located at a first-direction side but not at a second-direction side when viewed from the first device part, the first direction being from the first device part toward the second device part, the second direction being opposite to the first direction, the guard region being of the second conductivity type, a lower end of the guard region contacting the buried layer, an upper end of the guard region reaching an upper surface of the semiconductor layer;
a first semiconductor region located inside the first device part, the first semiconductor region being of the second conductivity type; and
a second semiconductor region located inside the second device part, the second semiconductor region being of the second conductivity type.

12. The device according to claim 11, wherein
the guard region is located at a third-direction side and a fourth-direction side when viewed from the first device part,
the third direction is orthogonal to the first direction, and
the fourth direction is opposite to the third direction.

13. The device according to claim 11, wherein
when viewed from the first device part, the guard region is located at a portion at the first-direction side of a region positioned at the third-direction side, the third direction being orthogonal to the first direction,
when viewed from the first device part, the guard region is located at a portion at the first-direction side of a region positioned at the fourth-direction side, the fourth direction being opposite to the third direction,
when viewed from the first device part, the guard region is not located at a portion at the second-direction side of the region of the first device part positioned at the third-direction side, and
when viewed from the first device part, the guard region is not located at a portion at the second-direction side of the region of the first device part positioned at the fourth-direction side.

14. The device according to claim 11, wherein
the guard region is located at a third-direction side but not at a fourth-direction side when viewed from the first device part,
the third direction is orthogonal to the first direction, and
the fourth direction is opposite to the third direction.

15. The device according to claim 11, wherein
the guard region is not located at a third-direction side or at a fourth-direction side when viewed from the first device part,
the third direction is orthogonal to the first direction, and
the fourth direction is opposite to the third direction.

16. The device according to claim 11, wherein
the device is rectangular when viewed from above,
the device comprises:
a first end surface parallel to the first direction; and
a second end surface orthogonal to the first end surface, and
an end surface of the first device part at the second-direction side faces the second end surface.

17. The device according to claim 14, wherein
the device is rectangular when viewed from above,
the device comprises:
a first end surface parallel to the first direction; and
a second end surface orthogonal to the first end surface,
an end surface of the first device part at the second-direction side faces the second end surface, and
an end surface of the first device part at the fourth-direction side faces the first end surface.

18. The device according to claim 11, further comprising:
a first source region located inside the first device part, the first source region being of the second conductivity type;
a first drain region located inside the first semiconductor region, the first drain region being of the second conductivity type;
a first gate insulating film located on the first device part;
a first gate electrode located on the first gate insulating film;
a second source region located inside the second device part, the second source region being of the second conductivity type;
a second drain region located inside the second semiconductor region, the second drain region being of the second conductivity type;
a second gate insulating film located on the second device part; and
a second gate electrode located on the second gate insulating film.

19. The device according to claim 18, further comprising:
a source pad located on the semiconductor layer and connected to the second source region; and
a drain pad located on the semiconductor layer and connected to the second drain region.

20. A semiconductor device, comprising:
a semiconductor substrate of a first conductivity type, the semiconductor substrate including
a first end surface parallel to a first direction, and
a second end surface parallel to a second direction orthogonal to the first direction;
a semiconductor layer located on the semiconductor substrate, the semiconductor layer being of the first conductivity type and including
a first device part, and
a second device part separated from the first device part in the first and second directions;
a buried layer located between the semiconductor substrate and the first device part, the buried layer being of a second conductivity type;
a guard region located at the first-direction side and the second-direction side when viewed from the first device part, the guard region not being located at a third-direction side or at a fourth-direction side when viewed from the first device part, the third direction being opposite to the first direction, the fourth direction being opposite to the second direction, the guard region being of the second conductivity type, a lower end of the guard region contacting the buried layer, an upper end of the guard region reaching an upper surface of the semiconductor layer;
a first semiconductor region located inside the first device part, the first semiconductor region being of the second conductivity type; and
a second semiconductor region located inside the second device part, the second semiconductor region being of the second conductivity type.

21. The device according to claim 20, wherein
an end surface of the first device part at the third-direction side faces the second end surface.

22. The device according to claim 20, wherein
an end surface of the first device part at the fourth-direction side faces the first end surface.

23. The device according to claim 22, wherein
an end surface of the second device part at the fourth-direction side faces the first end surface.
